(19) United States
(12) Patent Application Publication
(10) Pub. No.: US 2005/0250237 A1
(43) Pub. Date: Nov. 10, 2005

(54) Microstructured component and a method for producing a microstructured component

(76) Inventor: Markus Sonnemann, Reutlingen (DE)

Correspondence Address: KENYON & KENYON, ONE BROADWAY, NEW YORK, NY, 10004, US

(21) Appl. No.: 11/111,522

(22) Filed: Apr. 20, 2005

(30) Foreign Application Priority Data
Apr. 24, 2004 (DE) 102004020173.0

(51) Int. Cl. H01L 21/00

(52) U.S. Cl. 438/50

(57) ABSTRACT

A microstructured component includes at least: one chip having a microstructured area and a surface area, on which a nanostructured, self-organized coating is applied. The nanostructured, self-organized coating may be used as an antistick coating for repelling moisture or a surrounding molding material. Moreover, when using flip-chip and stack-chip technologies, an adhesive effect can be attained, so that additional joining areas can be dimensioned to be smaller.

### BACKGROUND INFORMATION

In this context, the microstructured component may, in particular, be a microelectronic or micromechanical component.

Micromechanical sensors are distinguished by movable structures which are moved because of outer influences such as acceleration, rotational rates or pressure, these movements being converted into voltage signals or capacitance signals and subsequently evaluated.

Accordingly, such components are also susceptible to mechanical disturbances which affect the component through the packaging. Particularly in automotive engineering with the wide temperature ranges and high climatic stresses occurring there, this sensitivity to mechanical stress often makes it difficult to use suitable modules with advantageous manufacturing methods, such as bonding techniques on the wafer level, etc., since in addition to the electronic properties of the component, the mechanical properties must also be kept stable over a wide temperature range and under the influence of moisture over long periods of time.

In part, yaw-rate sensors are covered on their upper and lower sides with a gel in order to establish a defined boundary surface between chip and packaging and to intercept mechanical stress. For optical applications, particularly infrared applications for gas detection, penetration of gel into the optical structures can impair correct functioning considerably.

### SUMMARY OF THE INVENTION

The microstructured component according to the present invention and the method for producing it have the advantage, in particular, that the properties of the microstructured component may be adapted well to the specific requirements. In this context, coatings having water-repellent or dirt-repellent effect may be applied, in particular. The present invention is based on the surprising insight that self-organizing, nanostructured coatings can also be used in the field of microstructured components, i.e., particularly in the field of microelectronics and micromechanics for developing advantageous effects. Thus, advantageous properties can be achieved compared to the use of metal coatings or lacquers.

According to the present invention, in particular, an antistick coating may be applied which, during the subsequent extrusion coating of the component into (in) a mold housing, forms a boundary layer, whereby it is possible to bring about a deliberate delamination of the chip or chips of the component from the molding material.

Moreover, the placement of chips one upon the other can be facilitated by an improvement of the adhesion, e.g., by a mechanical toothing of the coated areas of the chips. In this manner, it is possible to improve bonding techniques of flip-chip technology, in which a direct joining and contacting of two chips with their patterned surfaces is formed, and chip-stack technologies, in which chip stacks are formed, so that additional interconnecting regions by adhesive polymers or sealing-glass interconnections may be smaller.

The coatings may be applied, for example, by sol-gel processes or other processes.

### BRIEF DESCRIPTION OF THE DRAWINGS

FIG. 1 shows the process of coating a surface area of a component using a self-organizing nanostructure.

FIG. 2 shows, in a) a sensor wafer in top view and side view,
b) the growth of the antistick coating on the sensor wafer, and
c) the sensor wafer with antistick coating.

FIG. 3 shows side views of a sensor module with
a) antistick coating, and
b) antistick coating and molded housing.

FIG. 4 shows a flip-chip process for producing a sensor module:
a) a sensor wafer and ASIC wafer in top view,
b) the sensor wafer and ASIC wafer after coating in side view,
c) the coated side of a sensor chip or ASIC chip, and
d) the chip arrangement prior to joining.

### DETAILED DESCRIPTION

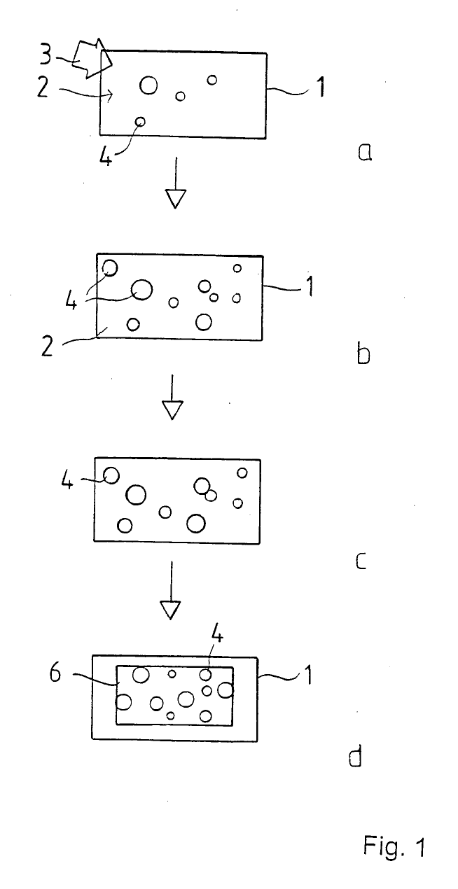

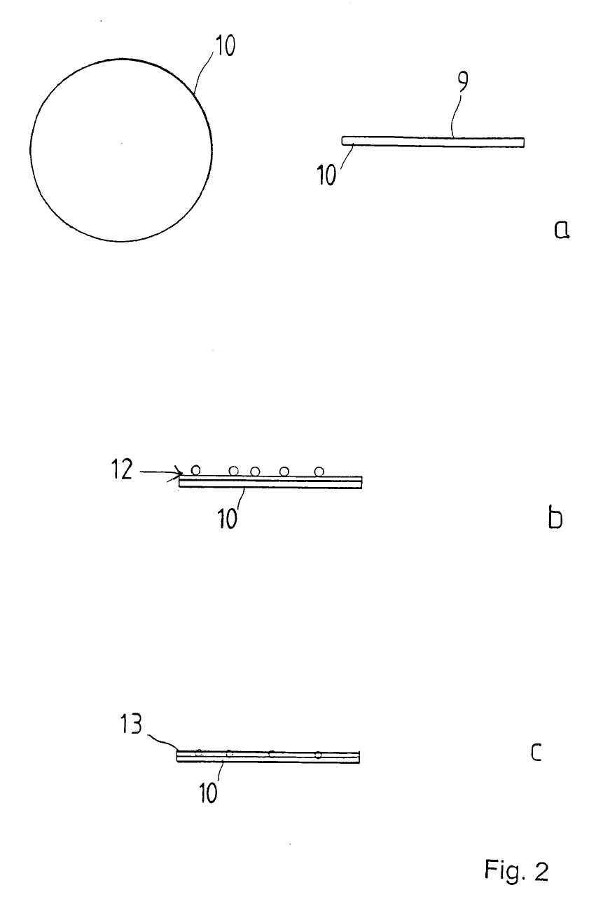

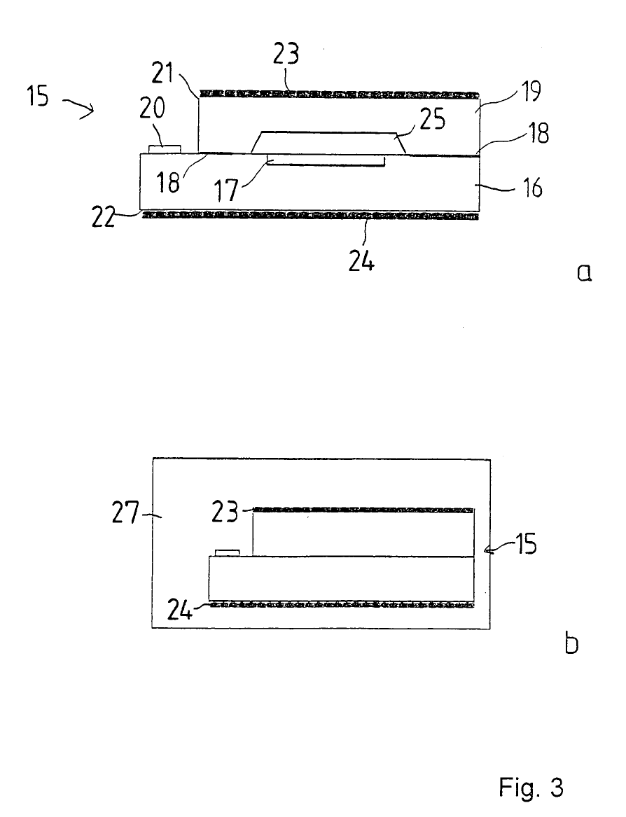

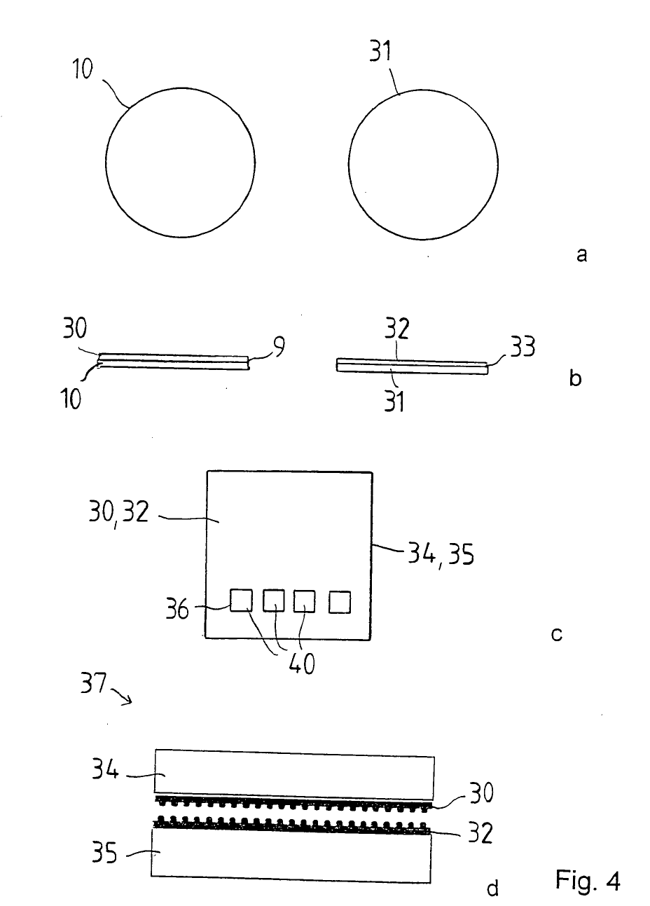

FIGS. 1a through 1d describe a sol-gel process for producing self-organizing nanostructures. It is based on the networking of organic and/or inorganic molecules to form nanoscale powder or networked particles by the addition of energy.

According to FIG. 1a, applied on a surface area 1 of a chip is a starting solution 2 having, for example, polymers, to which reaction accelerators 3 are fed. According to FIG. 1a, particles 4 thereby form in starting solution 2 which, according to FIG. 1b, increase in number and size and grow up to a critical size. According to FIG. 1c, the growth of particles 4 is stopped by a modification of the surface.

The amount of the particle growth may be restricted, first of all, by a stability criterion that limits growth above a critical value. For instance, such a stability criterion may be the ratio of the energy stored in the particle to the surface tension. Moreover, the particle growth may be blocked by a growth inhibitor which alters the energy balance in the system. This may be achieved, for example, by a change in the surface tension, whereby the wetting of the surface with water or an aqueous solution is altered, as may be achieved, for instance, by the addition of rinsing agent or other agents lowering the surface tension.

Particles 4 are subsequently networked by energy input, a networked surface structure 6 thereby being formed on surface area 1.

FIG. 2 describes the formation of self-organizing nanostructures as antistick coating, which may be used in particular on pressure sensors and mass flow sensors.

Applied on a sensor-wafer surface 9 of a sensor wafer 10 is a mixture 12 of organic and inorganic components with a thickness of a few nanometers, e.g., less than or equal to 10 nm. By a self-organized growth of mixture 12, an antistick coating 13, shown in FIG. 2c, forms as a nanostructured surface area on sensor wafer surface 9.

FIG. 3 shows a practical application of the coating shown in FIG. 2 in the case of a sensor module 15. Sensor module 15 features a sensor chip 16 having a microstructured area 17 for measuring an acceleration, torques, rates of rotation or also, for example, infrared radiation for use in a gas detector. Secured on sensor chip 16 by a vacuum-tight joint 18, e.g., sealing glass (low-melting, lead-containing glass), is a cap chip 19 in which a cavity 25, surrounding the microstructured area, is formed or epitaxially deposited. Sensor chip 16 has bonding pads 20, not covered by cap chip 19, for the contacting of sensor module 15.

According to the present invention, nano-antistick coatings 23, 24 are applied according to the process described in FIG. 2a through 2c on an outer surface 21 of cap chip 19 and a bottom side 22 of sensor chip 16, as shown in FIG. 3a.

According to FIG. 3b, after the contacting of bonding pads 20, entire sensor module 15 is subsequently injected or molded into a mold housing 27 made of a plastic material or molding-compound material. In so doing, a defined boundary layer with delamination of the surfaces and the molding compound develops between antistick coatings 23, 24 and the molding material of mold housing 27, which means any packaging stress, e.g., due to temperature changes, is no longer coupled into the active sensor structure in sensor module 15.

A use of self-organizing nanostructures for the preparation of boundary surfaces for subsequent assembly and joining techniques is described in FIG. 4. In this context, suitable topographies can be selectively represented that permit a robust joining in flip-chip or stacked-chip processes, in which two chips are placed one upon the other with their structured upper side, and a flip-chip module 37 having suitable contactings is thereby formed.

According to FIG. 4a, a nanostructured surface 30 is formed according to the process of FIGS. 1a through 1d on surface 9 of a sensor wafer 10 corresponding to FIG. 2. Moreover, a nanostructured coating 32 is formed on a surface of an ASIC wafer 31. After bonding, sensor chips 34 and ASIC chips 35 are formed from wafers 10 and 31 by dicing. According to FIG. 4c, bonding pads 36 are formed on chips 34, 35 or at least on sensor chip 34. In this context, bonding pads 36 may advantageously be left out from coatings 30, 32 by previous application of a lacquer.

According to the present invention, a bonding technique or joining technique may already be carried out on the wafer level, i.e., sensor wafer 10 is placed on ASIC wafer 31 and secured, whereupon the individual sensor modules may subsequently be separated by sawing from the wafer stack thus formed. In this connection, adhesion is achieved between nanostructured coatings 30 and 32 of sensor chip 34 and ASIC chip 35, e.g., by the toothing effect of the surface structures. This adhesion reduces the adhesion to be applied in the additional joining areas, so that the joining areas, formed, for example, as sealing-glass joints or also, for instance, as polymer joints, may be dimensioned to be smaller; for example, it is possible to provide only two or three joining points in addition to the adhesive effect of coatings 30, 32.

Bonding pads 36 themselves may also be coated, without impairing their electric conductivity, for example, by electrically conductive, nanostructured coatings 40 from SiC (silicon carbide) nano-crystallites for a sturdy joining.

1. A microstructured component comprising:
a chip having a microstructured area and a surface area, on which a nanostructured, self-organized coating is applied.

2. The microstructured component according to claim 1, wherein the nanostructured, self-organized coating is moisture-repellent.

3. The microstructured component according to claim 1, wherein the nanostructured, self-organized coating is dirt-repellent.

4. The microstructured component according to claim 1, wherein the nanostructured, self-organized coating has ceramic nanocrystals.

5. The microstructured component according to claim 1, wherein the nanostructured, self-organized coating has organic compounds.

6. The microstructured component according to claim 1, wherein a thickness of the nanostructured surface area is less than or equal to 20 nm.

7. The microstructured component according to claim 6, wherein the thickness is less than or equal to 10 nm.

8. The microstructured component according to claim 1, wherein the nanostructured, self-organized coating has particles networked by a sol-gel process.

9. The microstructured component according to claim 1, further comprising bonding pads having an electroconductive, microstructured surface coating.

10. The microstructured component according to claim 1, further comprising a molded housing composed of one of a plastic material and a molding compound, the rnanostructured, self-organized coating as an antistick coating forming a boundary layer without material locking with the one of the plastic material and the molding compound.

11. The microstructured component according to claim 10, further comprising a sensor module which includes a sensor chip having a microstructured area, a cap chip covering the microstructured area of the sensor chip, and a molded housing surrounding the chips, and the nanostructured antistick coatings are applied on an upper side of the cap chip and a bottom side of the sensor chip.

12. The microstructured component according to claim 1, further comprising a flip-chip module having two chips contacted and secured together with their structured sides, the chips being situated together via nanostructured, self-organized coatings, forming an adhesive effect.

13. The microstructured component according to claim 1, further comprising bonding pads coated with a conductive, nanocrystalline coating containing silicon carbide nanocrystallites.

14. A method for producing a microstructured component, comprising:
producing at least one chip; and
applying a self-organizing, nanostructured coating on a surface area of the chip.

15. The method according to claim 14, further comprising:
applying a starting solution on the surface area;
feeding reaction accelerators; and
after a formation of particles, ending a particle growth, and supplying energy, so that the particles network to form the self-organizing, nanostructured coating.

16. The method according to claim 14, wherein the self-organizing, nanostructured coating is applied on contact areas of one of (a) two chips and (b) two wafers, and further comprising subsequently placing the one of the chips and the wafers one upon the other with the coatings, forming an adhesion.

17. The method according to claim 14, wherein the self-organizing, nanostructured coatings are applied on outer surfaces of the component, and further comprising subsequently extruding a housing composed of one of a plastic material and a molding compound around the component.
